(19) United States
(12) Patent Application Publication
(10) Pub. No.: US 2010/0026530 A1
(43) Pub. Date: Feb. 4, 2010

(54) METHOD OF GENERATING KEY CODE IN COORDINATE RECOGNITION DEVICE AND APPARATUS USING THE SAME

(76) Inventors: Jae Kyung Lee, Gyeongsangbuk-do (KR); Ji Min Heo, Gyeongsanbuk-do (KR)

Correspondence Address: KED & ASSOCIATES, LLP, P.O. Box 221200, Chantilly, VA, 20153-1200, US

(21) Appl. No.: 12/442,882

(22) PCT Filed: Mar. 23, 2007
(86) PCT No.: PCT/KR2007/001427

§ 371 Date: Mar. 25, 2009

(30) Foreign Application Priority Data
Sep. 29, 2006 (KR) 1020060095728

(51) Int. Cl. H03M 11/02

(52) U.S. Cl. 341/22

(57) ABSTRACT

A method and apparatus for generating a key code in a coordinate recognition device (video device controller 120) enable key code generation by a single instance of manipulation of a controller (140) by a user, obviating repetitive keypad manipulation and thereby facilitating controller operation. A coordinate recognition (120) device is provided with a touch pad (110) having a touch pattern of a predetermined shape, enabling a touch trajectory to be recognized in a simple manner. The apparatus includes a touch pad (110) having a predetermined touch pattern; a coordinate recognition unit (120) for recognizing coordinate values corresponding to a touch trajectory executed with respect to the touch pad (110), a controller (140) for calculating values of a direction, speed, and distance of the touch trajectory using the recognized coordinate values and for outputting a movement command signal based on the calculated values; and a key code generator (150) for generating a key code corresponding to the movement command signal. The method includes steps of recognizing coordinate values corresponding to a touch trajectory executed with respect to a touch pad (110) having a predetermined touch pattern; calculating a direction, speed, and distance of the touch trajectory using the recognized coordinate values; and generating a movement command signal corresponding to the calculated values, the generated movement command signal corresponding to a specific key code.

### TECHNICAL FIELD

The present invention relates to a coordinate recognition device and more particularly to a method of generating a key code in a coordinate recognition device and an apparatus using the same.

### BACKGROUND ART

The controller of a video device (e.g., a television receiver) having a video display device may be provided with a keypad including a plurality of keys for channel selection, volume adjustment, etc. Such a keypad may be provided to a remote controller for controlling a wide variety of standard television functions.

To execute a specific function, a user of the video device presses (activates) a specific function key on the controller, or remote controller, which transmits to the television receiver a coded signal corresponding to the activated function. Accordingly, such a controller may be provided with numerous keys, including frequently used and infrequently used keys. Since a great number of keys tends to encumber the user, who may have difficulty in correctly searching and identifying the desired key, the video device is typically provided with a virtual keypad using an on-screen display (OSD) function. In doing so, an OSD keypad may include keys, as icons, that can therefore be excluded from the controller's keypad, i.e., a physical keypad.

The keys of the OSD keypad thus enable execution of any number of functions as desired. In essence, the corresponding keys of the virtual keypad operate in the same manner as those of the physical keypad, which are typically provided as tactile switches. As such, one pressing of any of the physical keys, as a single instance of the corresponding tactile switch operation, results in the generation of one key code to operate (manipulate) the OSD keypad.

Therefore, to move an OSD object or icon highlight (display curser) on the OSD keypad, for example, to effect a channel changing or volume control function or to navigate an OSD menu of a video device, a user must sequentially perform a series of pressing operations of the corresponding key of the physical keypad to step through a range of movement, typically using an arrow key (e.g., an up/down or left/right key) of the remote controller, so that the object or highlight is moved from an initial display location to a desired display location. This repetitious operation of the keypad is cumbersome to the user.

### DISCLOSURE OF INVENTION

Accordingly, the present invention is directed to an apparatus and method of key code generation in a coordinate recognition device that substantially obviate one or more of the problems due to limitations and disadvantages of the related art.

An object of the present invention is to provide a method of generating a key code in a coordinate recognition device and an apparatus using the same, by which key codes for performing a wide range of functions can be selectively generated without repetitive keypad manipulation by a user.

Another object of the present invention is to provide a method of generating a key code in a coordinate recognition device and an apparatus using the same, by which a specific key code of a range of key codes corresponding to a range of function control can be selectively generated by a single instance of manipulation of a controller by a user.

Another object of the present invention is to provide a method of generating a key code in a coordinate recognition device and an apparatus using the same, which simplifies implementation of an economical key code generation apparatus.

Another object of the present invention is to provide a method of generating a key code in a coordinate recognition device and an apparatus using the same, which facilitates user operation and control of the various functions of a video device, including OSD menu navigation.

Additional features and advantages of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these and other advantages and in accordance with the purpose of the present invention, as embodied and broadly described, there is provided an apparatus for generating a key code in a coordinate recognition device. The apparatus comprises a touch pad having a predetermined touch pattern; a coordinate recognition unit for recognizing coordinate values corresponding to a touch trajectory executed with respect to the touch pad; a controller for calculating values of a direction, speed, and distance of the touch trajectory using the recognized coordinate values and for outputting a movement command signal based on the calculated values; and a key code generator for generating a key code corresponding to the movement command signal. The predetermined touch pattern of the touch pad is one selected from the group consisting of a vertically oriented rectangular shape, a horizontally oriented rectangular shape, a round annular shape, a hexagonal annular shape, a square annular shape, a downwardly curved crescent shape, an upwardly curved crescent shape, a cross-type shape, and a hybrid pattern formed of at least two of the rectangular, annular, and crescent shapes.

According to another aspect of the present invention, there is also provided a method of generating a key code in a coordinate recognition device. The method comprises recognizing coordinate values corresponding to a touch trajectory executed with respect to a touch pad having a predetermined touch pattern; calculating a direction, speed, and distance of the touch trajectory using the recognized coordinate values; and generating a movement command signal corresponding to the calculated values, the generated movement command signal corresponding to a key code output to control a video device.

It is to be understood that both the foregoing general description and the following detailed description are exemplary and explanatory and are intended to provide further explanation of the invention as claimed.

### BRIEF DESCRIPTION OF DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIG. 1 is a block diagram of an apparatus for generating key codes in a coordinate recognition device according to the present invention;

FIGS. 2A-2J are plan-view diagrams respectively illustrating a number of predetermined touch patterns for the touch pad of FIG. 1;

FIG. 3 is a flowchart illustrating a method of generating a key code in a coordinate recognition device according to a first embodiment of the present invention;

FIGS. 4A and 4B are diagrams for explaining the embodiment of FIG. 3;

FIG. 5 is a diagram for explaining a method of generating a key code in a coordinate recognition device according to a second embodiment of the present invention;

FIGS. 6A and 6B are diagrams for explaining a key code generation method according to a third embodiment of the present invention; and

FIG. 7 is a flowchart illustrating a method of generating a key code in a coordinate recognition device according to the third embodiment of the present invention.

### BEST MODE FOR CARRYING OUT THE INVENTION

According to the present invention, a touch pad having a touch pattern of a predetermined shape is introduced to a coordinate recognition device as input means to a controller of a video device. The predetermined shape of the touch pattern enables a touch trajectory to be recognized in a simple manner and enables a full control of any one of several functions of the video device, including channel changing, volume control, and menu navigation, which are conventionally performed by a series of controller manipulations or by repetitive instances of button pressing operations. Throughout the following specification, a touch trajectory is a manually input command executed by a user of the controller to generate a prescribed movement command signal and is thus generated by the user manually or physically touching the touch pad and following a dragging motion (track) across the surface of the touch pad. As such, a touch trajectory has properties of directionality, travel speed, and travel distance in consideration of the touch trajectory's termini (i.e., start point and corresponding end point) expressed in terms of x-y coordinate values. Also, a recognized touch trajectory according to the present invention may have a width consistent with a human finger in contact with the touch pad. Meanwhile, the touch pad of the present invention is typically operated by a user's finger, but the present invention is applicable to touch pads for use with other types of solid objects, whether opaque or transparent, conductive or non-conductive.

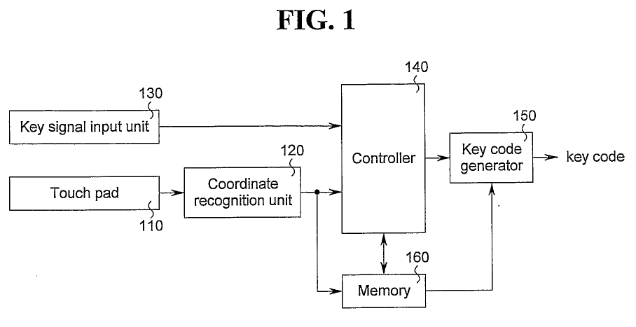

Referring to FIG. 1, an apparatus for generating a key code according to the present invention includes a touch pad 110 having a predetermined touch pattern; a coordinate recognition unit 120 for recognizing coordinate values corresponding to a touch trajectory applied by a user as an input to the touch pad and for outputting a set of coordinate values, including start and end coordinates, corresponding to the touch trajectory; a key signal input unit 130, having a plurality of keys, for generating a key signal input according to a user selection of one or more of the keys; a controller 140 for outputting a movement command signal for moving a cursor, highlight, or other object in correspondence to a direction, speed, and distance of the touch trajectory; a key code generator 150 for generating a specific key code based on the movement command signal supplied from the controller; and a memory 160 for storing a system program of the controller and a full set of coordinate values corresponding to surface points of the predetermined touch pattern. The movement command signal of the controller 140 may be variously generated, in accordance with the system program stored in the memory 160, based on one of the first, second, and third embodiments of the present invention.

That is, according to the stored system program, the controller 140 calculates the direction, distance, and speed of a touch trajectory based on the coordinate values received from the coordinate recognition unit 120, according to a key signal input that may be concurrently or correlatively received from the key signal input unit 130, to output a movement command signal corresponding to the calculated direction, speed, and distance of the touch trajectory. In outputting the movement command signal, the controller 140 controls the key code generator 150 to generate a unique key code indicative of the movement command signal. At the same time, the controller 140 determines, based on an intrinsic touch type, whether a touch trajectory corresponds to an up/down (vertical) motion, a right/left (horizontal) motion, or a circular/elliptical motion.

The stored information of the memory 160 may be set by the manufacturer prior to sale of the controller of a video device, e.g., a television remote controller, including a coordinate recognition device. That is, an apparatus for generating a key code according to the present invention may be embodied in a remote controller, using a coordinate recognition device including a touch pad and coordinate recognition unit according to the present invention.

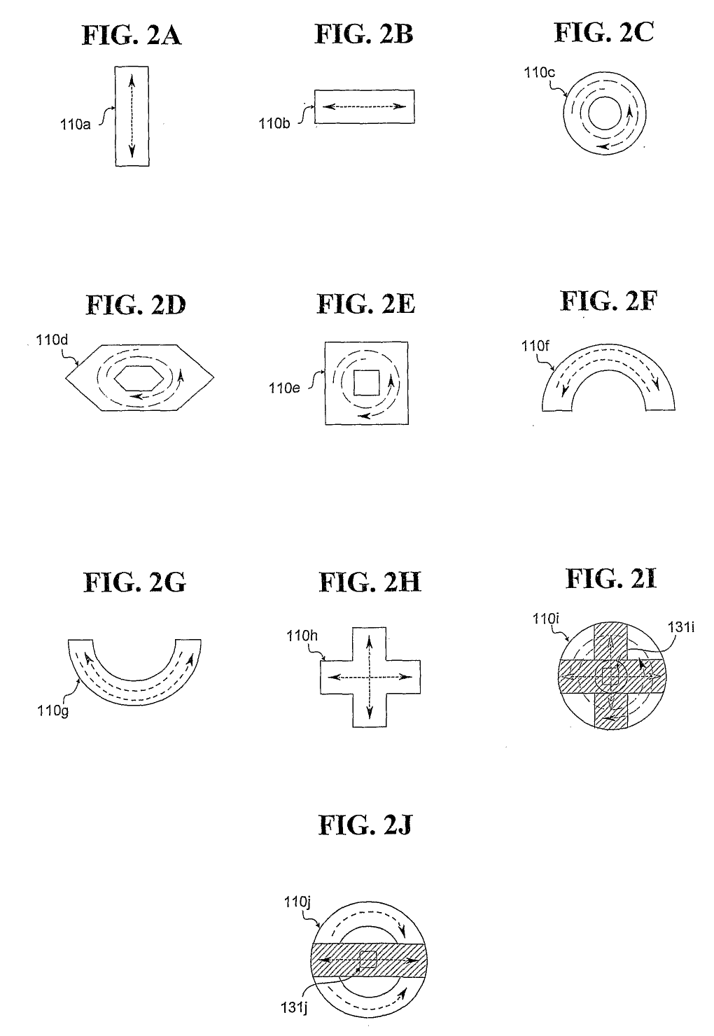

FIGS. 2A-2J illustrate predetermined touch patterns 110a-110j, respectively, which are suggested patterns for the touch pad of FIG. 1. For example, the touch patterns 110a and 110b each have a rectangular shape, which may be extended lengthwise to be oriented vertically as shown in FIG. 2A or oriented horizontally as shown in FIG. 2B. The touch patterns 110c, 110d, and 110e each have an essentially annular shape, which may be formed as a round touch pattern as shown in FIG. 2C, as a hexagonal touch pattern as shown in FIG. 2D, or as a square touch pattern as shown in FIG. 2E, and any of the annular touch patterns may be formed to foster a circular touch trajectory (as in FIG. 2C or 2E) or an elliptical touch trajectory (as in FIG. 2D). That is, though not specifically shown, the touch pattern 110c may have a more oval shape generally, the touch pattern 110d may have a more regular hexagon shape generally, and the touch pattern 110e may have a more rectangular shape generally, and the hollows formed by the above annular touch patterns may have a size (area) varying according to shape. The touch patterns 110f and 110g each have a crescent (semicircular) shape, which may be curved above a hollow (downwardly curved) as shown in FIG. 2F or curved below a hollow (upwardly curved) as shown in FIG. 2G The general shape of the touch pad 1110 may correspond to the shape of the touch pattern.

Furthermore, combinations of patterns may be variously configured, as exemplified by the touch patterns 110h-110j. For example, the rectangular touch patterns 110a and 110b may be combined to form a cross-type touch pattern 110h as shown in FIG. 2H, and the cross-type touch pattern may be combined with an annular touch pattern (e.g., touch pattern 110c) to form a hybrid touch pattern 110i as shown in FIG. 2I. A simplified hybrid pattern 110j may be formed as shown in FIG. 2J by combining the annular touch pattern 110c with one of the rectangular touch patterns 110a and 110b crossing the center of the annular pattern. The hybrid touch patterns 110i and 110j may be constructed as two superposed layers.

In addition, a selection button may be arranged in the hollow of a touch pattern and may correspond to a conventional tactile switch of a keypad. For example, the hollow of the touch pattern 110i or 110j may be provided with a corresponding a selection button 131i or 131j in the form of a tactile switch. In the present invention, the selection button of a two-layer hybrid touch pattern is included in the key signal input unit 130 and may be disposed beneath a cross-type touch pattern (FIG. 2I) or rectangular touch pattern (FIG. 2J) placed over an annular circular pattern. In this case, inclusion of a selection button enables a selection of one pattern (element) of a hybrid touch pattern, for example, the cross-type touch pattern or annular touch pattern of FIG. 2I or the rectangular touch pattern or annular touch pattern of FIG. 2J. Yet, in the present invention, the controller 140 is configured with the coordinate recognition unit 120 according to the stored coordinate values of the memory 160, such that characteristics of the touch trajectory can be automatically determined by the intrinsic nature (basic type) of a touch motion performed by the user, without pressing the selection button.

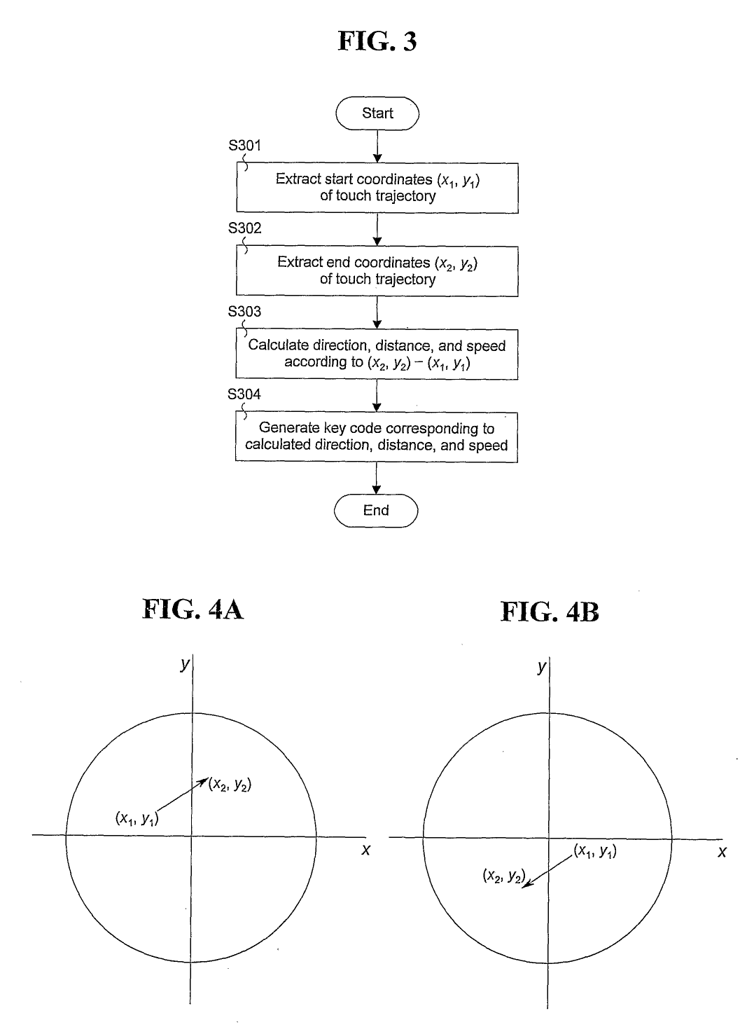

Referring to FIG. 3, illustrating a method of generating a key code in a coordinate recognition device according to a first embodiment of the present invention, a key code is generated according to the direction, distance, and speed of a touch trajectory executed with respect to of the touch pad 110 having a predetermined touch pattern, such as the touch patterns 110a-110j. In doing so, the controller 140 first extracts start coordinates (x₁, y₁) and end coordinates (x₂, y₂), in sequence, through the coordinate recognition unit 120 in response to the touch trajectory (S301, S302), and the extracted coordinates are recognized by the coordinate recognition unit 120. Then, based on the recognized coordinate values, the controller 140 calculates a direction, distance, and speed of the touch trajectory to output a corresponding movement command signal (S303). Here, the directionality of the touch trajectory may be determined according to a process illustrated in FIGS. 4A and 4B, each showing a touch trajectory expressed by coordinate values (x₁, y₁) indicating the trajectory's start point and by coordinate values (x₂, y₂) indicating the trajectory's end point, where the respective trajectories represent opposite directions.

In the first embodiment, an increasing direction of a touch trajectory as shown in FIG. 4A or a decreasing direction of a touch trajectory as shown in FIG. 4B is determined by the stored system program, according to a movement command signal output by the controller 140 in correspondence with the recognized coordinates of each touch trajectory. Determination of touch trajectory direction by the controller 140 is facilitated by the touch pattern of the touch pad 110. Since the coordinate values corresponding to the predetermined touch pattern are previously stored in the memory 160 by the manufacturer—such that the distances and directions between the coordinate values are likewise stored or can be known—the controller 140 can determine the direction of any touch trajectory by a simple system program. Such a system program may compare a recognized touch trajectory's start and end coordinate values with each other and with zero, and based on the comparison results, determines a corresponding direction (i.e., increasing or decreasing) as shown in the example of Table 1.

TABLE 1

| | y₂ − y₁ > 0 | (y₂ = y₁) > 0 | y₂ − y₁ = 0 | y₂ − y₁ < 0 |
|---|---|---|---|---|
| x₂ − x₁ > 0 | increasing | increasing | decreasing | decreasing |
| (x₂ = x₁) > 0 | decreasing | — | — | increasing |
| (x₂ = x₁) < 0 | increasing | — | — | decreasing |
| x₂ − x₁ < 0 | decreasing | decreasing | increasing | increasing |

As exemplified in Table 1, in accordance with the stored system program, when a touch motion is performed by the user with respect to the predetermined touch pattern of the touch pad 110 such that a touch trajectory is recognized by the coordinate recognition unit 120, one direction will be determined, for instance, as an increasing direction (i.e., a first direction) such that the substantially opposite direction will be determined as a decreasing direction (i.e., a second direction).

Meanwhile, the speed of a touch trajectory can be found by dividing the distance (x₂, y₂)−(x₁, y₁) of the touch trajectory by a positive integer n, which is representative of a corresponding time of the touch trajectory. The distance of the touch trajectory be calculated using the same coordinate values, according to a variety of conventional techniques, for example, based on a determination of values for each of an x-coordinate movement distance (x₂−x₁) and a y-coordinate movement distance (y₂−y₁), and since the touch trajectory speed is determined based on the distance calculation, it can be said that a touch trajectory speed characteristic inherently includes a touch trajectory distance characteristic. On the other hand, once touch trajectory distance is found, the controller 140 may likewise determine the time of the touch trajectory by detecting the respective times of the start and end points of an executed touch trajectory and calculating a difference value or by using an internal clock or step counter to count the time of the touch trajectory generation. Then, using this time value and the known distance, the controller 140 can calculate the speed of the touch trajectory.

Provided with speed and direction values calculated as above, the key code generator 150 generates a key code corresponding to the touch trajectory's speed and direction (S304). An example of such key code generation, where three different touch trajectory speeds may be determined with respect to each of an increasing touch trajectory direction and a decreasing touch trajectory direction, is shown in Table 2.

TABLE 2

| direction | speed 1 | speed 2 | speed 3 |
|---|---|---|---|
| increasing | key code 1 | key code 2 | key code 3 |
| decreasing | key code 4 | key code 5 | key code 6 |

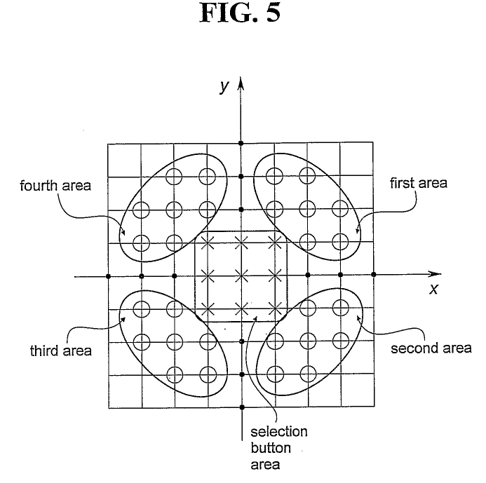

FIG. 5 demonstrates a method of generating a key code in a coordinate recognition device according to a second embodiment of the present invention. As shown, a touch pattern includes a plurality touch pattern areas, for example, first to fourth areas arranged within the touch pattern with respect to x and y axes. Here, information including one set of coordinate values corresponding to each of the arranged areas of the touch pattern are respectively stored in the memory 160 by the manufacturer, thereby enabling the controller 140 to determine touch trajectory direction, distance, and speed according to recognized coordinates of an executed touch trajectory. In particular, the stored information includes an indication of a distance between each of the plurality of touch pattern areas, which are preferably arranged such that adjacent areas are spaced equidistantly from one another.

In the example of FIG. 5, the plurality of touch pattern areas are arranged in correspondence to an annular touch pattern (e.g., touch pattern 110c), which includes a selection button area, but the second embodiment may utilize any touch pattern and the selection button area may be omitted. The recognized coordinates (shown as circled coordinates) correspond collectively to one touch pattern area, to be differentiated from other touch pattern areas, such that a touch trajectory that passes through one of at least two touch pattern areas can establish a direction, distance, and speed. Accordingly, if a touch trajectory passing through at least two touch pattern areas arranged along the path of an annular touch pattern is generated, one of first and second touch trajectory directions is determined by the controller 140, based on the system program stored in the memory 160 and the sequentially detected coordinate values output from the coordinate recognition unit 120 in accordance with the touch trajectory applied to the touch pad 110. These directions may correspond to clockwise and counterclockwise directions, i.e., opposite directions, and thus may be correlated to increasing and decreasing directions of the touch trajectory. A more accurate touch trajectory speed value may be determined by a touch trajectory that passes through three or more touch pattern areas, such as a touch trajectory generated clockwise from the fourth area to the third area, whereby the controller 140 and system program recognizes the direction as a first direction, say, an increasing direction. Conversely, a touch trajectory generated counterclockwise from the first area to the second area, whereby the controller 140 and system program recognizes the direction as a second direction, say, a decreasing direction (i.e., opposite to the first direction).

In this embodiment, touch trajectory distance can be found very simply based on a sum of the preset distances between adjacent touch pattern areas. Then, as in the first embodiment, the touch trajectory speed may be calculated using a touch trajectory time value. Subsequently, the key code generator 150 generates a key code corresponding to the calculated direction, distance, and speed values, for example, as in Table 2.

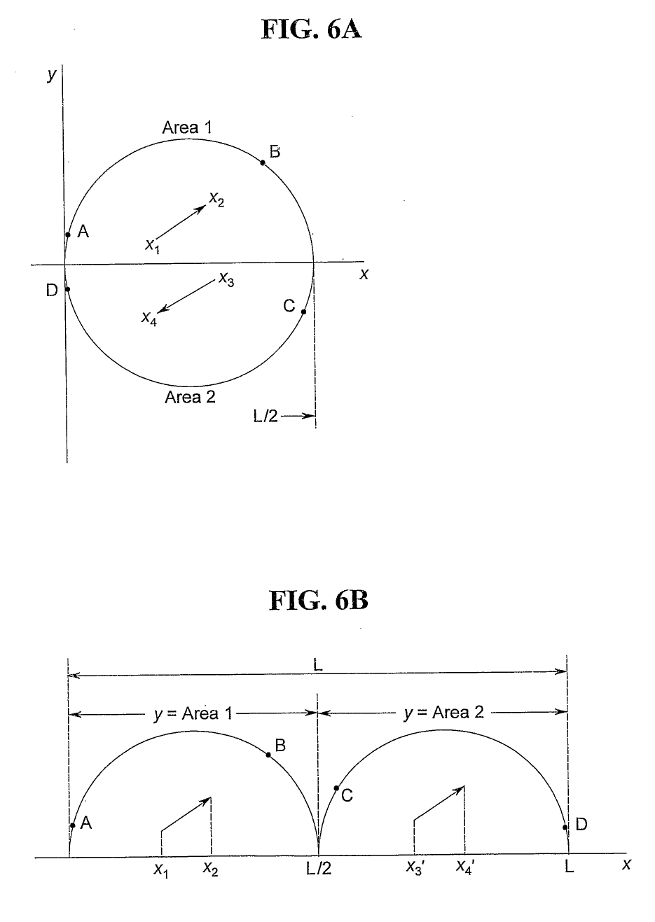

FIGS. 6A and 6B demonstrate a key code generation method according to a third embodiment of the present invention, which assumes an annular touch pattern inherently including two y-axis areas of the touch pattern, namely, an upper y-axis area (or “Area 1”) and a lower y-axis area (or “Area 2”), which are delineated by the x axis. Here, points A-D are shown for reference purposes only. That is, the two y-axis areas of FIG. 6A are shown in FIG. 6B, in which the same areas are reconfigured for point-for-point symmetry between Areas 1 and 2, centering vertically on the maximum x-coordinate value (L/2), to thereby reposition the coordinates of the lower y-axis area. In other words, in FIG. 6A, Areas 1 and 2 correspond to the physical nature of the touch pattern, but in FIG. 6B, the lower y-axis area is repositioned such that Areas 1 and 2 both lie above the x axis theoretically and extend to twice the maximum x-coordinate value (L).

Therefore, due to the above correspondence between Areas 1 and 2, an x-axis coordinate x of Area 1 and the x-axis coordinate x′ of Area 2 exhibit a relationship as expressed by Formula 1.

$${x}^{′} = \frac{L}{2} + ( \frac{L}{2} - x ) \qquad [ Formula 1 ]$$

where x′ is the x-axis coordinate of the repositioned lower y-axis area, where x is the x-coordinate of the lower y-axis area without any reconfiguring of the touch pad area, and where L is twice the maximum x-coordinate value. Accordingly, the x-axis coordinate x₃ or x₄ of FIG. 6A is repositioned in FIG. 6B, to lie in the theoretically repositioned lower y-axis area, and can be represented as x-axis coordinate x₃′ or x₄′ per Formula 2.

$${x}_{3}^{′} = \frac{L}{2} + ( \frac{L}{2} - {x}_{3} ) \\ {x}_{4}^{′} = \frac{L}{2} + ( \frac{L}{2} - {x}_{4} ) \qquad [ Formula 2 ]$$

Subsequently, the controller 140 uses the system program to determine values for the touch trajectory's direction, distance, and speed, which are calculated based on the repositioned x-axis coordinates, namely, the x′ values of Formula 2 (per Formula 1). Here, the direction of a touch trajectory may be determined using Formulae 3 and 4.

(x₂−x₁), (x₄′−x₃′)>0 [Formula 3]

(x₂−x₁), (x₄′−x₃′)<0 [Formula 4]

That is, as shown in FIG. 6B, the values x₁ and x₂ of an Area 1 touch trajectory or the values x₃′ and x₄′ of an Area 2 touch trajectory are applied to each of Formulae 3 and 4. An increasing touch trajectory direction is determined when Formula 3 is true, and a decreasing touch trajectory direction is determined when Formula 4 is true. In other words, for either of the upper and lower y-axis areas, the direction of the touch trajectory is determined as an increasing direction (i.e., a first direction) if a difference between an x-axis value of start and end coordinates of the touch trajectory is greater than zero, and the direction of the touch trajectory is determined as a decreasing direction (i.e., a second direction) if a difference between an x-axis value of start and end coordinates of the touch trajectory is less than zero.

After determining the touch trajectory direction as above, a corresponding touch trajectory speed is calculated. The controller 140 may determine the speed of a touch trajectory based on its distance, by dividing the absolute value of the difference between the x coordinates by n, i.e., a positive integer corresponding to the touch trajectory time, as in

$$\frac{\vert {x}_{2} - {x}_{1} \vert}{n}$$

for Area 1 trajectories or

$$\frac{\vert {x}_{4}^{′} - {x}_{3}^{′} \vert}{n}$$

for Area 2 trajectories. By thus calculating touch trajectory direction, distance, and speed, the key code generator 150 generates a key code corresponding to the calculated direction, distance, and speed values, for example, as in Table 2.

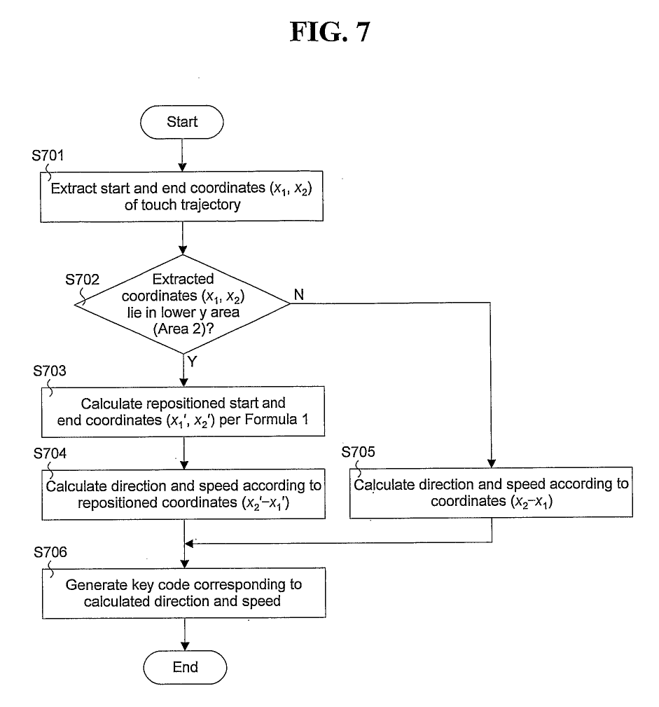

Referring to FIG. 7, illustrating a method of generating a key code in a coordinate recognition device according to the third embodiment, a key code is generated according to the direction, distance, and speed of a touch trajectory executed with respect to of the touch pad 110 having a predetermined touch pattern, such as the touch patterns 110a-110j. First, the controller 140 sequentially extracts start and coordinates through the coordinate recognition unit 120 in response to the touch trajectory. In doing so, the controller 140 first extracts the start and end coordinates (x₁, x₂), and the extracted values are stored in the memory 160 (S701). The controller 140 then determines whether or not the coordinates lie in Area 2 (S702), and if so, uses Formula 1 to find a repositioned start coordinate x₁′ and a repositioned end coordinate x₂′ (S703).

Thus, if the coordinates x₁ and x₂ lie in Area 2, the controller 140 calculates a direction and speed of the touch trajectory according to the repositioned coordinates (x₂′−x₁′), defining a touch trajectory distance in Area 2 (S704). On the other hand, if the coordinates x₁ and x₂ lie in Area 2, the controller 140 calculates a direction and speed of the touch trajectory according to the original coordinates (x₂−x₁), defining a touch trajectory distance in Area 1 (S705). That is, if both x coordinates lie in Area 2, i.e., in the lower y-axis area, the repositioned coordinate values are used for calculating touch trajectory direction and speed; if both x coordinates lie in Area 1, i.e., in the upper y-axis area, the stored (original) coordinate values are used for calculating touch trajectory direction and speed.

As in the first and second embodiments, the key code generator 150 generates, a key code corresponding to the touch trajectory's speed and direction based on the values calculated as above (S706). That is, according to the third embodiment, an annular touch pattern is divided into an upper area (Area 1) and a lower area (Area 2) of an x-y axis assignment with respect to the touch pad, and the two areas are configured for point-for-point symmetry between the upper and lower y-axis areas, centering vertically on a maximum x-coordinate point of the original touch pattern area, to thereby reposition coordinates of the lower y-axis area, so that the direction and speed of the touch trajectory may be determined using repositioned x coordinates.

### INDUSTRIAL APPLICABILITY

By adopting the present invention, in manipulating on-screen display objects using a user interface (e.g., a remote controller provided with a touch pad) to control various functions and settings of a video device (e.g., a television receiver), and particularly functions exhibiting continuity over a range of control, object movement on the screen is performed quickly and easily using a simple program. The touch pad has a touch pattern imparted with a predetermined shape to enable recognition of a touch trajectory in a simple manner. Also, in generating key codes using the touch pad of the present invention, the speed of a touch trajectory may be considered as well as its directionality and travel distance.

Accordingly, the present invention enables key codes for performing a wide range of functions to be selectively generated without repetitive keypad manipulation by a user. That is, a specific key code of a range of key codes corresponding to a range of function control can be selectively generated by a single instance of manipulation of a controller by a user, to facilitate user operation and control of the various functions of a video device, including OSD menu navigation, while simplifying implementation of an economical key code generation apparatus.

While the present invention has been described and illustrated herein with reference to one or more preferred embodiments, it will be apparent to those skilled in the art that various modifications can be made in the present invention without departing from the spirit or scope of the invention. Thus, it is intended that the present invention covers such modifications provided they come within the scope of the appended claims and their equivalents.

What is claimed is:

1. An apparatus for generating a key code in a coordinate recognition device, the apparatus comprising:
a touch pad having a predetermined touch pattern;
a coordinate recognition unit for recognizing coordinate values corresponding to a touch trajectory executed with respect to said touch pad;
a controller for calculating values of a direction, speed, and distance of the touch trajectory using the recognized coordinate values and for outputting a movement command signal based on the calculated values; and
a key code generator for generating a key code corresponding to the movement command signal.

2. The apparatus of claim 1, wherein the predetermined touch pattern of said touch pad is one selected from the group consisting of a vertically oriented rectangular shape, a horizontally oriented rectangular shape, a round annular shape, a hexagonal annular shape, a square annular shape, a downwardly curved crescent shape, an upwardly curved crescent shape, a cross-type shape, and a hybrid pattern formed of at least two of the rectangular, annular, and crescent shapes.

3. The apparatus of claim 2, wherein any one of the round annular shape, hexagonal annular shape, and square annular shape is formed to foster one of a circular touch trajectory and an elliptical touch trajectory.

4. The apparatus of claim 2, wherein the predetermined touch pattern is a hybrid pattern formed of at least two of the shapes.

5. The apparatus of claim 4, further comprising:
a selection button for selectively enabling elements of the hybrid pattern.

6. The apparatus of claim 5, wherein the selection button is arranged in a hollow of the predetermined touch pattern.

7. The apparatus of claim 1, wherein said controller determines a type of motion being executed for the touch trajectory according to a touch motion applied to said touch pad.

8. The apparatus of claim 7, wherein the determined motion type is one of an up/down motion, a right/left motion, and a circular motion.

9. The apparatus of claim 1, further comprising:
a key signal input unit, having a plurality of keys, for generating a key signal input to said controller according to a user selection of at least one of the keys.

10. The apparatus of claim 1, wherein said controller calculates the touch trajectory values according to a key input signal supplied by a user.

11. A method of generating a key code in a coordinate recognition device, the method comprising:
recognizing coordinate values corresponding to a touch trajectory executed with respect to a touch pad having a predetermined touch pattern;
calculating a direction, speed, and distance of the touch trajectory using the recognized coordinate values; and
generating a movement command signal corresponding to the calculated values, the generated movement command signal corresponding to a key code output to control a video device.

12. The method of claim 11, further comprising:
storing in memory a plurality of key codes for controlling the video device, the stored key codes arranged according to speed, time, and distance of the touch trajectory,
wherein the key code is output to the video device with reference to the stored key codes.

13. The method of claim 11, further comprising:
storing in memory information of the touch pad, the stored information including a full set of coordinate values corresponding to the predetermined touch pattern.

14. The method of claim 13, wherein the stored information further includes values of distances between the coordinate values of the predetermined touch pattern and values of directions between the coordinate values of the predetermined touch pattern.

15. The method of claim 13, wherein the coordinate values of the predetermined touch pattern are stored by a manufacturer of the coordinate recognition device.

16. The method of claim 11, said command signal generating comprising:
determining, by referencing the stored information, the direction and distance of the touch trajectory according to the recognized coordinate values of the touch trajectory, to calculate the speed of the touch trajectory by dividing the determined distance by a positive integer representative of a touch trajectory time.

17. The method of claim 11, said command signal generating comprising:
determining, by referencing the stored information, the direction of the touch trajectory according to the recognized coordinate values of the touch trajectory; and
finding an x-coordinate movement distance of the touch pad and a y-coordinate movement distance of the touch pad according to the recognized coordinate values of the touch trajectory, to calculate the distance of the touch trajectory based on the coordinate movement distances of the touch pad and to calculate the speed of the touch trajectory by dividing the calculated distance by a positive integer representative of a touch trajectory time.

18. The method of claim 11, said command signal generating comprising:
determining, by referencing the stored information, the direction and distance of the touch trajectory according to the recognized coordinate values of the touch trajectory; and
finding a time of the touch trajectory using a step counter, to calculate the speed of the touch trajectory by dividing the determined distance by the time of the touch trajectory.

19. The method of claim 11, said command signal generating comprising:
determining, by referencing the stored information, the direction of the touch trajectory according to the recognized coordinate values of the touch trajectory;
finding an x-coordinate movement distance of the touch pad and a y-coordinate movement distance of the touch pad according to the recognized coordinate values of the touch trajectory, to calculate the distance of the touch trajectory based on the coordinate movement distances of the touch pad; and
finding a time of the touch trajectory using a step counter, to calculate the speed of the touch trajectory by dividing the calculated distance by the time of the touch trajectory.

20. The method of claim 11, said command signal generating comprising:
dividing the predetermined touch pattern of the touch pad into a plurality of touch pattern areas; and
respectively storing in memory information including one set of coordinate values corresponding to each of the plurality of touch pattern areas, the stored information further including an indication of a distance between each of the plurality of touch pattern areas,
wherein the distance of the touch trajectory is calculated using the stored distance information.

21. The method of claim 20, wherein the touch pattern areas are arranged such that adjacent areas are spaced equidistantly from one another.

22. The method of claim 20, wherein the predetermined touch pattern includes one of a rectangular touch pattern and a crescent touch pattern.

23. The method of claim 22, wherein, if the executed touch trajectory travels in a first direction with respect to at least two of the touch pattern areas, the direction of the touch trajectory is determined as an increasing direction and wherein, if the executed touch trajectory travels in a second direction with respect to at least two of the touch pattern areas, the direction of the touch trajectory is determined as a decreasing direction.

24. The method of claim 20, wherein the predetermined touch pattern includes an annular touch pattern.

25. The method of claim 24, wherein, if the executed touch trajectory is clockwise with respect to at least two of the touch pattern areas, the direction of the touch trajectory is determined as a first direction and wherein, if the executed touch trajectory is counterclockwise with respect to at least two of the touch pattern areas, the direction of the touch trajectory is determined as a second direction.

26. The method of claim 20, further comprising:
counting, using an internal clock, a time corresponding to the execution of the touch trajectory,
wherein the speed of the touch trajectory is calculated using the counted time.

27. The method of claim 11, said command signal generating comprising:
assigning x- and y-axes to an area of the touch pad corresponding to the predetermined touch pattern;
dividing the touch pad area along the x axis into an upper y-axis area and a lower y-axis area; and
reconfiguring the touch pad area for point-for-point symmetry between the upper and lower y-axis areas, centering vertically on a maximum x-coordinate point of the touch pad area, to thereby reposition coordinates of the lower y-axis area,
wherein the direction and speed of the touch trajectory are calculated using the repositioned x-axis coordinates.

28. The method of claim 27, wherein the x-axis coordinate of the repositioned lower y-axis area is expressed by
$${x}^{′} = \frac{L}{2} + ( \frac{L}{2} - x )$$
where x′ is the x-axis coordinate of the repositioned lower y-axis area, where x is the x-coordinate of the lower y-axis area without said reconfiguring of the touch pad area, and where L is twice the maximum x-coordinate value.

29. The method of claim 27, wherein the direction of the touch trajectory is determined as a first direction if a difference between an x-axis value of start and end coordinates of the touch trajectory is greater than zero and wherein the direction of the touch trajectory is determined as a second direction if a difference between an x-axis value of start and end coordinates of the touch trajectory is less than zero.

30. The method of claim 27, wherein the speed of the touch trajectory is calculated by dividing an absolute value of a difference between an x-axis value of start and end coordinates of the touch trajectory by a positive integer representative of a touch trajectory time.

31. The method of claim 27, wherein the speed of the touch trajectory is calculated according to a touch trajectory time obtained using an internal clock.

32. The method of claim 11, wherein the key code includes a signal for moving an object on an on-screen display of the video device, the moved object controlling a function of the video device.
